(19) United States
(12) Patent Application Publication
(10) Pub. No.: US 2012/0328468 A1
(43) Pub. Date: Dec. 27, 2012

(54) PROCESSED HIGH-PURITY COPPER MATERIAL HAVING UNIFORM AND FINE CRYSTALLINE STRUCTURE, AND PROCESS FOR PRODUCTION THEREOF

(75) Inventors: Satoshi Kumagai, Iwaki-shi (JP); Masato Koide, Osaka (JP)

(73) Assignee: MITSUBISHI MATERIALS CORPORATION, Chiyoda-ku, Tokyo (JP)

(21) Appl. No.: 13/580,186

(22) PCT Filed: Mar. 4, 2011
(86) PCT No.: PCT/JP2011/055039

§ 371 Date: Aug. 21, 2012

(30) Foreign Application Priority Data
Mar. 5, 2010 (JP) 2010-048516

(51) Int. Cl. C22C 9/00; C23C 14/14; B21B 3/00; C22F 1/08

(52) U.S. Cl. 420/469; 204/298.13; 72/201

(57) ABSTRACT

This worked high-purity copper material includes Cu having a purity of 99.9999% by mass or more, wherein an average crystal grain size is in a range of 20 μm or less, and in a grain size distribution of crystal grains, an area ratio of crystal grains having grain sizes that exceed 2.5 times the average crystal grain size is in a range of less than 10% of an area of the entire crystal grains. This method for producing a worked high-purity copper material includes: subjecting an ingot composed of high-purity copper having a Cu purity of 99.9999% by mass or more to hot forging at an initial temperature of 550° C. or higher, and then water-cooling the ingot; subsequently, subjecting the ingot to warm forging at an initial temperature of 350° C. or higher, and then water-cooling the ingot; subsequently, subjecting the ingot to cold cross-rolling at a total reduction ratio of 50% or more; and subsequently, subjecting the ingot to stress relief annealing at a temperature of 200° C. or higher.

### TECHNICAL FIELD

The present invention relates to a worked (processed) high-purity copper material having a uniform and fine crystalline structure, which is suitably used as, for example, a sputtering target, and a method for producing the same.

The present application claims priority on Japanese Patent Application No. 2010-48516 filed on Mar. 5, 2010, the content of which is incorporated herein by reference.

### BACKGROUND ART

Examples of a process for forming a conductive film and the like when producing semiconductor devices such as IC, LSI, and ULSI include sputtering in which a high-purity copper target including fine crystal grains is used, electrolysis which is carried out in an electroplating bath using a high-purity copper anode, and the like. The high-purity copper preferably has a purity of 99.9999% by mass or more and preferably includes fine crystal grains having an average crystal grain size of 200 μm or less.

For example, as shown in Patent Documents 1 and 2, high-purity copper having fine crystal grains is produced as follows. Firstly, copper is melted and cast in vacuum or an inert gas atmosphere so as to produce a high-purity copper ingot having a purity of 99.9999% by mass or more. The high-purity copper ingot is heated to a temperature of 550° C. to 650° C., the heated high-purity copper ingot is subjected to hot forging, and then is subjected to cold processing. Next, stress relief annealing is carried out in a temperature range that fulfills an initial temperature range of 350° C. to 500° C. Cold processing and stress relief annealing are repeatedly carried out, and, finally, cold processing is carried out. Thereby, a worked high-purity copper material is produced.

In the above-described technique of the related art, a purity of 99.9999% by mass or more can be secured by using a material having a purity of 99.9999% by mass or more. However, there is a problem in that it is difficult to stably produce fine crystal grains having an average grain size of 200 μm or less in an industrial manner.

As a result, various techniques are proposed in order to stably produce a finer crystalline structure.

For example, in Patent Document 3, a high-purity copper ingot having a purity of 99.9999% by mass or more is subjected to hot forging at a temperature of 300° C. to 500° C., and then is subjected to cold processing. Next, stress relief annealing is carried out. Thereby, a worked high-purity copper material is obtained which is composed of fine crystal grains having an average crystal grain size of 10 μm to 50 μm and is used as a sputtering target or an electroplating anode.

In addition, in Patent Document 4, a high-purity copper material is cooled to a temperature of −50° C. or lower, and then the high-purity copper material is subjected to processing so as to introduce strains to the high-purity copper. Next, the high-purity copper, to which strains are introduced, is recrystallized at a temperature of approximately 320° C. or lower. Thereby, a worked high-purity copper material having a crystal grain size of approximately 10 μm or less is obtained.

In Patent Document 5, hot forging is carried out at a temperature of higher than 300° C., and then intermediate annealing is carried out as necessary. After that, cold rolling is carried out. Thereby, a worked high-purity copper material having an average crystal grain size of 1μm to approximately 50 μm is produced.

In Patent Document 6, hot forging is carried out, and then water quenching is carried out. After that, cold rolling is carried out. Thereby, a worked high-purity copper material having relatively uniform crystal grain sizes and an average crystal grain size of 50 μm or lower is produced.

In recent years, an increase in the size of a Si wafer has led to an increase in the size of a sputtering target. As the size of a sputtering target increases, there is a demand for preventing the occurrence of defects on the wafer. Specifically, there is a demand for improvement in the uniformity of the thickness of a film formed through sputtering or prevention of the occurrence of abnormal discharge.

### PRIOR ART DOCUMENT

### Patent Document

Patent Document 1: Japanese Unexamined Patent Application, First Publication No. 10-195609

Patent Document 2: Japanese Unexamined Patent Application, First Publication No. 10-330923

Patent Document 3: Japanese Unexamined Patent Application, First Publication No. 2001-240949

Patent Document 4: Japanese Unexamined Patent Application, First Publication No. 2004-52111

Patent Document 5: Published Japanese Translation No. 2005-533187 of the PCT International Publication

Patent Document 6: Published Japanese Translation No. 2009-535518 of the PCT International Publication

### DISCLOSURE OF THE INVENTION

### Problems to be Solved by the Invention

In consideration of the above-described circumstances, the present invention aims to provide a worked high-purity copper material having a uniform and fine crystalline structure, and a method for producing the same. The worked high-purity copper material can secure uniformity in the thickness of a film formed through sputtering and can prevent the occurrence of abnormal discharge even in the case where the size of a sputtering target is increased.

### Means for Solving the Problems

The present inventors have thoroughly studied the relationship between the occurrence of abnormal discharge and the crystalline structure of a worked high-purity copper material when sputtering is carried out using a sputtering target composed of the worked high-purity copper material. As a result, it is found that the average crystal grain size of crystal grains in the worked high-purity copper material that composes the sputtering target and uniformity in the crystal grain size have a large influence on the characteristics of a sputtered film (a film formed through sputtering).

For example, according to the production processes shown in Patent Documents 3 to 6, high-purity copper having relatively small crystal grain sizes is obtained. When the distribution of the crystal grain sizes is measured, it is found that the distribution width of the crystal grain sizes is wide. Particularly, in the case where a worked high-purity copper material having a purity of 99.9999% by mass or more is manufactured by increasing the purity, it becomes difficult to uniformly miniaturize crystal grains. In addition, even when the average crystal grain size is small, the variation in the grain sizes is large; and therefore, a worked high-purity copper material having a small average crystal grain size and uniform crystal grain sizes throughout the entire worked material cannot be obtained.

Therefore, the inventors have carried out additional studies regarding a process for producing a worked high-purity copper material having a crystalline structure which has a small average crystal grain size and uniform crystal grain sizes throughout the entire worked material. As a result, it is found that a worked high-purity copper material having a uniform and fine crystalline structure can be produced by the following process. Firstly, an ingot composed of high-purity copper having a purity of 99.9999% by mass or more is subjected to hot forging at an initial temperature of 550° C. or higher. Thereby, the cast structure collapses, and then water cooling is carried out. Next, warm forging is carried out at an initial temperature of 350° C. or higher, and then water cooling is carried out. Thereby, miniaturization and uniformization of the structure are achieved, and furthermore, the progress of recrystallization is suppressed. Next, cold cross rolling is carried out at a total reduction ratio of 50% or more. Thereby, the entire structure is further miniaturized and uniformalized, and furthermore, strains for recrystallization are applied. Next, stress relief annealing is carried out at a temperature of 200° C. or higher. Thereby, strains are removed, and recrystallization proceeds at the same time. As a result, a worked high-purity copper material can be produced in which the average crystal grain size is in a range of 20 μm or less, and, in the grain size distribution of the crystal grains, the area ratio of crystal grains having grain sizes that exceed 2.5 times the average crystal grain size is in a range of less than 10% of the area of the entire crystal grains.

For example, in the case where a large-diameter sputtering target for a Si wafer with φ300 mm is manufactured using the worked high-purity copper material and the target is used in sputtering, sputtering can be uniformly carried out without the occurrence of abnormal discharge. As a result, the occurrence of defects on the wafer can be reduced.

The invention has been made based on the above-described finding, and has the following features.

(1) There is provided a worked high-purity copper material having a uniform and fine crystalline structure according to an aspect of the invention which includes Cu having a purity of 99.9999% by mass or more, wherein an average crystal grain size is in a range of 20 μm or less, and in a grain size distribution of crystal grains, an area ratio of crystal grains having grain sizes that exceed 2.5 times the average crystal grain size is in a range of less than 10% of an area of the entire crystal grains.

(2) In the worked high-purity copper material having a uniform and fine crystalline structure according to the above (1), the worked high-purity copper material may be a sputtering target.

(3) There is provided a method for producing the worked high-purity copper material having a uniform and fine crystalline structure of the above (1) or (2) according to an aspect of the invention, the method includes: subjecting an ingot composed of high-purity copper having a Cu purity of 99.9999% by mass or more to hot forging at an initial temperature of 550° C. or higher, and then water-cooling the ingot; subsequently, subjecting the ingot to warm forging at an initial temperature of 350° C. or higher, and then water-cooling the ingot; subsequently, subjecting the ingot to cold cross-rolling at a total reduction ratio of 50% or more; and subsequently, subjecting the ingot to stress relief annealing at a temperature of 200° C. or higher.

(4) In the method for producing the worked high-purity copper material having a uniform and fine crystalline structure according to the above (3), as the ingot composed of the high-purity copper having a purity of 99.9999% by mass or more, a high-purity copper ingot may be used that is produced through unidirectional solidification and has no casting defects composed of shrinkage cavities or voids.

(5) In the method for producing the worked high-purity copper material having a uniform and fine crystalline structure according to the above (3) or (4), in the hot forging, hot forging of stretching or compressing may be carried out at least one or more times at an initial temperature of 550° C. to 900° C.

(6) In the method for producing the worked high-purity copper material having a uniform and fine crystalline structure according to the above (5), in the hot forging of stretching or compressing, the ingot may be compressed in a solidification direction, and then the ingot may be stretched while the ingot is forged in multi-directions of at least two or more directions which are perpendicular to the solidification direction of the ingot.

(7) In the method for producing the worked high-purity copper material having a uniform and fine crystalline structure according to any one of the above (3) to (6), in the warm forging, warm forging of stretching or compressing may be carried out at least one or more times at an initial temperature of 350° C. to 500° C.

(8) In the method for producing the worked high-purity copper material having a uniform and fine crystalline structure according to the above (7), in the warm forging of stretching or compressing, the ingot may be compressed in a solidification direction, and then the ingot may be stretched while the ingot is forged in multi-directions of at least two or more directions which are perpendicular to the solidification direction of the ingot.

(9) In the method for producing the worked high-purity copper material having a uniform and fine crystalline structure according to any one of the above (3) to (8), the stress relief annealing may be carried out in a temperature range of 200° C. to 400° C.

### Effects of the Invention

In the case where a sputtering target is manufactured using the worked high-purity copper material according to the one aspect of the invention and sputtering is carried out using the sputtering target, sputtering can be uniformly carried out without the occurrence of abnormal discharge. Therefore, the occurrence of defects on a wafer can be reduced.

### BRIEF DESCRIPTION OF THE DRAWINGS

FIG. 1 is a schematic explanatory view for explaining an example of a hot forging step in a method for producing a worked high-purity copper material of the present embodiment.

FIG. 2 is a schematic explanatory view for explaining an example of a warm forging step in a method for producing a worked high-purity copper material of the present embodiment.

### BEST MODE FOR CARRYING OUT THE INVENTION

The method for producing a worked high-purity copper material according to an embodiment of the invention will be described specifically and in detail using the accompanying drawings.

Firstly, high-purity copper having a purity of 99.9999% by mass or more is melted, for example, in a high-purity inert gas atmosphere such as high-purity Ar gas, a reducing gas atmosphere such as nitrogen gas including 2% to 3% of CO gas, or a vacuum atmosphere at a temperature of 1150° C. to 1300° C. so as to produce molten metal. Next, the molten metal is solidified so as to produce an ingot of high-purity copper having a purity of 99.9999% by mass or more.

In the embodiment, a copper ingot is produced through, for example, unidirectional solidification. When the molten metal is subjected to unidirectional solidification, gaseous components are emitted through the uppermost surface of the ingot.

Therefore, even in the case where trapped gas is present, the trapped gas can be easily removed through surface grinding or the like. In addition, compared to an ingot obtained by an ordinary casting method, the number of occurred shrinkage cavities or voids is small, and the yield ratio is improved.

Meanwhile, the method for producing the copper ingot is not limited to unidirectional solidification, and a high-purity copper ingot having no casting defects such as shrinkage cavities, voids, or cracking can be obtained even through, for example, semi-continuous casting or the like.

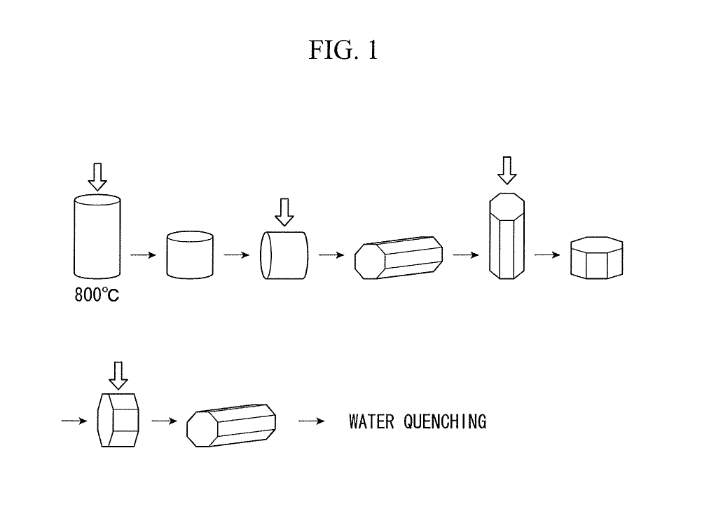

FIG. 1 is a schematic explanatory view for explaining an example of a hot forging step in the method for producing a worked high-purity copper material of the present embodiment.

The above-described ingot of high-purity copper having an unidirectionally-solidified structure and a purity of 99.9999% by mass or more is heated at an initial temperature of 550° C. to 900° C. (800° C. in FIG. 1), and hot forging is carried out.

In the hot forging step, firstly, forging is carried out in the solidification direction of the high-purity copper ingot. When the thickness becomes ½ or less, the ingot is placed transversely. While the ingot is rotated, the ingot is struck from the circumferential directions so as to be stretched (expanded) up to a length that is twice or more the original transverse length; and thereby, multi-directional forging of stretching or compressing is carried out so as to make a prismatic (prism-shaped) hot-forged material. Next, the prismatic hot-forged material is made to stand upright, and forging is carried out again in the axial direction of the prismatic hot-forged material. When the thickness becomes ½ or less, the hot-forged material is placed transversely again. While the hot-forged material is rotated, the hot-forged material is struck from the circumferential directions so as to be stretched (expanded) up to a length that is twice or more the original transverse length; and thereby, multi-directional forging of stretching or compressing is carried out again. The above-described steps are carried out repeatedly; and thereby, the cast structure of the ingot collapses. In addition, after the hot forging, the hot-forged material is water-cooled. In FIG. 1, a method for obtaining an octagonal prismatic (octagonal prism-shaped) hot-forged material is exemplified; however, the method is not limited thereto, and, for example, a quadratic prismatic (quadratic prism-shaped) hot-forged material may be obtained.

The manufactured ingot has a large crystal grain size of approximately 1000 μm to 200000 μm. However, the cast structure of the ingot collapses by carrying out the hot forging, and the crystal grain size is miniaturized to approximately 80 μm to 150 μm.

As such, the hot forging step in the embodiment is preferably hot forging of stretching or compressing that is carried out at least one or more times at an initial temperature of 550° C. to 900° C.

Here, in the case where the initial temperature of the hot forging is lower than 550° C., the cast structure remains. On the other hand, in the case where forging is carried out at an initial temperature of higher than 900° C., due to heat generation during the forging or the like, there is a concern about melting of the ingot, or unnecessary wasting of energy. Therefore, the initial temperature of the hot forging is set to be in a range of 550° C. to 900° C.

In addition, in order to eliminate the heterogeneity (crystal grain size) of the cast structure, it is preferable to conduct multi-directional forging of stretching or compressing in which the ingot is forged in multi-directions to be stretched (expanded).

Furthermore, the reason why the hot-forged material is water-cooled after the hot forging is particularly because the crystal grains in the collapsed cast structure are prevented from growing and coarsening due to residual heat in the hot-forged material.

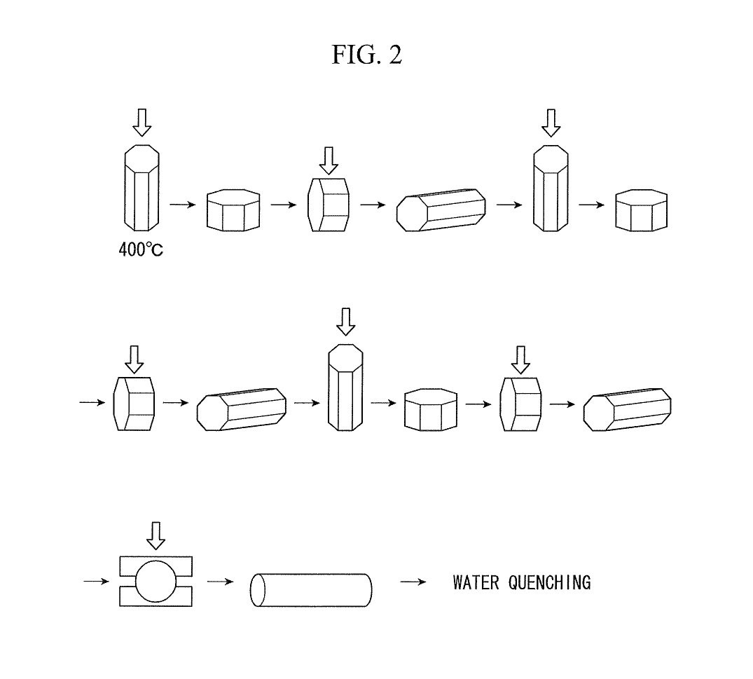

FIG. 2 is a schematic explanatory view for explaining an example of a warm forging step in the method for producing a worked high-purity copper material of the present embodiment.

The prismatic hot-forged material that is manufactured through the hot forging is subjected to warm forging at an initial temperature of 350° C. to 500° C.

For example, firstly, the prismatic hot-forged material that is heated to 420° C. is subjected to warm forging in the axial direction. When the thickness becomes ½ or less, the warm-forged material is placed transversely. While the warm-forged material is rotated, the warm-forged material is struck from the circumferential directions so as to be stretched (expanded) up to a length that is twice or more the original transverse length; and thereby, multi-directional forging of stretching or compressing is carried out. Next, the prismatic warm-forged material is made to stand upright, and forging is carried out again in the axial direction of the prismatic warm-forged material. When the thickness becomes ½ or less, the warm-forged material is placed transversely again. While the warm-forged material is rotated, the warm-forged material is struck from the circumferential directions so as to be stretched (expanded) up to a length that is twice or more the original transverse length; and thereby, multi-directional forging of stretching or compressing is carried out again. These steps are carried out repeatedly. When the corners of the prismatic warm-forged material are rounded to some extent, tap forging is carried out; and thereby, a columnar warm-forged material is manufactured. Water cooling is carried out before the temperature of the warm-forged material is decreased to 300° C. or lower.

A crystal grain structure having an average crystal grain size of approximately 30 μm to 80 μm and uniform grain sizes throughout the entire warm-forged material is formed by carrying out the warm forging.

In the case where the temperature of the warm forging is lower than 350° C., there is a high risk of the material buckling during forging, and a worked structure remains. On the other hand, in the case where the temperature of the warm forging exceeds 500° C., there is a concern that the structure may coarsen during the process. Therefore, the temperature of the warm forging is set to be in a range of 350° C. to 500° C.

In addition, the reason why the water cooling is carried out before the temperature of the warm-forged material is decreased to 300° C. or lower after the warm forging is because the occurrence of the heterogeneous growth of crystal grains is prevented, and the partial coarsening of crystal grains is also prevented.

The columnar warm-forged material that is manufactured through the warm forging is subjected to cold rolling (cold cross rolling) while rotating at a certain angle, that is, while crossing the columnar warm-forged material so that the total reduction ratio becomes at least 50% or more. In the case where the total reduction ratio is less than 50%, the amount of applied strains are small, and there is a fear that statistic recrystallization lacks. In addition, in order to enhance the uniformity of the structure, cold rolling is carried out while crossing the material.

During the cold rolling, the conditions are preferably controlled so that the temperature of the copper material does not exceed 100° C. Thereby, the release of strains can be prevented, and recrystallization can be suppressed. Meanwhile, the temperature of the copper material is more preferably in a range of 85° C. or lower, and most preferably in a range of 70° C. or lower.

The high-purity cold-rolled copper material (cold-rolled material) that is obtained by the above-described step is subjected to stress relief annealing in a temperature range of 200° C. to 400° C. In the case where the annealing temperature is lower than 200° C., there is a case in which a worked structure remains. In the case where the annealing temperature exceeds 400° C., coarsening of crystal grains begins, and there is a case in which a fine crystalline structure, which is an object of the embodiment, cannot be obtained. Therefore, the temperature of stress relief annealing is set to be in a range of 200° C. to 400° C.

The worked high-purity copper material of the embodiment is obtained by the above-described production method. The worked high-purity copper material includes high-purity copper having a purity of 99.9999% by mass or more, and the average crystal grain size is in a range of 20 μm or less. In the grain size distribution of crystal grains, the area ratio of crystal grains having grain sizes that exceed 2.5 times the average crystal grain size is in a range of less than 10% of the area of the entire crystal grains. The entire worked high-purity copper material has a uniform crystalline structure, and the crystalline structure is fine.

In the case where the average crystal grain size exceeds 20 μm, the effect that is obtained from miniaturization of crystal grains cannot be expected when the worked high-purity copper material is used as a sputtering target. In the case where the area ratio of crystal grains having grain sizes that exceed 2.5 times the average crystal grain size is in a range of 10% or more of the area of the entire crystal grains, the uniformity of the crystalline structure becomes insufficient. Therefore, the effect that is obtained from miniaturization of crystal grains cannot be expected in long-term sputtering. As a result, in the embodiment, it is determined that the average crystal grain size is in a range of 20 μm or less, and, in the grain size distribution of crystal grains, the area ratio of crystal grains having grain sizes that exceed 2.5 times the average crystal grain size is in a range of less than 10% of the area of the entire crystal grains.

### EXAMPLES

Next, the embodiment will be described specifically using examples. High-purity copper ingots having a Cu purity of 99.9999% by mass or more and dimensions of a diameter: 250 mm and a length: 600 mm were produced. The high-purity copper ingots were produced through unidirectional solidification, and in the production step, the surface of molten metal was solidified at the end. Therefore, casting defects such as shrinkage cavities or voids were not present in the ingots, and the ingots had robust cast structures.

As a result of measuring the sizes of crystal grains in each of the ingots, it was found that the sizes of the crystal grains were in a range of 1000 μm to 200000 μm, the variation in the crystal grain size was large, and any of the crystal grains were coarse.

The average crystal grain size and the variation in the crystal grain size (=the area ratio of crystal grains having grain sizes that exceed 2.5 times the average crystal grain size) of the measured ingot are shown in Table 2.

(A) The high-purity copper ingot was held at the temperatures shown in Table 1, and, firstly, the high-purity copper ingot was subjected to hot forging in a solidification direction of the high-purity copper ingot as shown in FIG. 1. The high-purity copper ingot was placed transversely when the thickness became ½ or less. While the ingot was rotated, the ingot was struck from the circumferential directions so as to be stretched (expanded) up to a length that was twice or more the original transverse length; and thereby, multi-directional forging of stretching or compressing was carried out so as to make a prismatic (prism-shaped) hot-forged material. Next, the prismatic hot-forged material was made to stand upright, and forging was carried out again in the axial direction of the prismatic hot-forged material. When the thickness became ½ or less, the hot-forged material was placed transversely again. While the hot-forged material was rotated, the hot-forged material was struck from the circumferential directions so as to be stretched (expanded) up to a length that was twice or more the original transverse length; and thereby, multi-directional forging of stretching or compressing was carried out again.

The hot-forged material on which the multi-directional forging of stretching or compressing was carried out two times was water-quenched. The temperature of the hot-forged material when the water quenching was carried out is shown in Table 1.

With regard to the hot-forged material, the measured average crystal grain size and the measured variation in the crystal grain size (=the area ratio of crystal grains having grain sizes that exceed 2.5 times the average crystal grain size) are shown in Table 2.

(B) Next, the hot-forged material was heated to the temperatures shown in Table 1, and warm forging was carried out by repeating multi-directional forging of stretching or compressing three times as shown in FIG. 2.

The warm forging was finished when the diameter of the warm-forged material became 150 mm, and water quenching was carried out. The temperature of the warm-forged material when the water quenching was carried out is shown in Table 1.

With regard to the warm-forged material, the measured average crystal grain size and the measured variation in the crystal grain size (=the area ratio of crystal grains having grain sizes that exceed 2.5 times the average crystal grain size) are shown in Table 2.

(C) The warm-forged material was subjected to cold rolling while rotating the warm-forged material so as to obtain the total reduction ratio shown in Table 1 so that the target diameter shown in Table 1 was obtained. When the temperature of the cold-rolled material became the temperature shown in Table 1, the cold-rolled material was water-quenched.

(D) The cold-rolled material was subjected to stress relief annealing under the temperature conditions shown in Table 1, and then water quenching was carried out. The annealed material that had been subjected to the stress relief annealing was subjected to facing and surface pickling, and then the average crystal grain size and the variation in the crystal grain size (=the area ratio of crystal grains having grain sizes that exceed 2.5 times the average crystal grain size) were measured. The measured values are shown in Table 2.

Through the respective steps of the above-described (A) to (D), worked high-purity copper materials (referred to as Examples) 1 to 10 were produced which had the uniform and fine crystal grains of the embodiment shown in Table 2.

(Measurement of Average Crystal Grain Size)

Crystal grain boundaries were specified using an EBSD measurement apparatus (S4300-SE manufactured by Hitachi High Technologies Corp., and OIM Data Collection manufactured by EDAX/TSL) in which a field emission scanning electron microscope was used and analysis software (OIM Data Analysis ver. 5.2 manufactured by EDAX/TSL). The measurement conditions were the measurement range: 680×1020 μm/measurement step: 2.0 μm / scanning time: 20 msec/point.

Firstly, an electron beam was irradiated to each of the measurement points (pixels) in the measurement range on the specimen surface using a scanning electron microscope. Measurement points for which the orientation difference between adjacent measurement points became 15° or more were determined to be crystal grain boundaries, and the orientation difference was obtained through orientation analysis by a backscattered electron beam analysis method.

The number of crystal grains in the observation area was computed from the obtained crystal grain boundaries. The total length of the crystal grain boundaries in the observation area was divided by the number of the crystal grains, and an area of the crystal grains was calculated. Then, the average crystal grain size was obtained from the calculated area on condition that the crystal grain deems to be a circle.

(Measurement of the Variation in Crystal Grain Size)

A grain size distribution map was prepared through the above-described measurement, and the variation was computed from the grain size distribution map.

For comparison, the high-purity copper ingots which were manufactured as described above was subjected to hot forging, warm forging, cold rolling, and stress relief annealing under the conditions shown in Table 3, and the high-purity copper ingots had a Cu purity of 99.9999% by mass or more and dimensions of a diameter: 250 mm and a length: 600 mm. Thereby, worked high-purity copper materials of Comparative Examples 1 to 10 shown in Table 4 (referred to as Comparative Examples) were produced. Meanwhile, among the conditions shown in Table 3, at least one condition is outside the scope of the embodiment.

With regard to Comparative Examples 1 to 10 produced above, similarly to the invention, the average crystal grain size and the variation in the crystal grain size (=the area ratio of crystal grains having grain size s that exceed 2.5 times the average crystal grain size) were measured.

The measured values are shown in Table 4.

TABLE 1

| | Hot forging | | Warm forging | | Cold rolling | | | Stress relief | |
|---|---|---|---|---|---|---|---|---|---|
| | Forging | Water quenching | Forging | Water quenching | Total | Target | Water quenching | annealing | |
| Production | temperature | start temperature | temperature | start temperature | reduction | diameter | start temperature | Temperature | Time |
| symbol | (° C.) | (° C.) | (° C.) | (° C.) | ratio (%) | (mm) | (° C.) | (° C.) | (min) |
| A | 816 | 628 | 416 | 369 | 75 | 530 | 40 | 200 | 120 |
| B | 801 | 603 | 420 | 352 | 60 | 550 | 42 | 200 | 120 |
| C | 783 | 598 | 486 | 343 | 83 | 460 | 41 | 200 | 120 |
| D | 764 | 590 | 382 | 303 | 95 | 460 | 52 | 300 | 60 |
| E | 750 | 583 | 355 | 342 | 90 | 530 | 51 | 250 | 60 |
| F | 738 | 552 | 413 | 313 | 85 | 530 | 48 | 250 | 60 |
| G | 686 | 513 | 482 | 324 | 70 | 530 | 40 | 250 | 180 |
| H | 650 | 458 | 423 | 315 | 70 | 530 | 38 | 300 | 180 |
| I | 590 | 426 | 366 | 314 | 75 | 460 | 39 | 300 | 180 |
| J | 601 | 449 | 393 | 359 | 65 | 530 | 43 | 300 | 180 |

TABLE 2

| | | High-purity copper ingot with | | Hot-forged | | Warm-forged | | Stress-relief- | |
|---|---|---|---|---|---|---|---|---|---|
| | | unidirectionally solidified structure | | material | | material | | annealed material | |
| | | | Area ratio of crystal | | Area ratio of crystal | | Area ratio of crystal | | Area ratio of crystal |
| | Pro- | Average | grains having grain | Average | grains having grain | Average | grains having grain | Average | grains having grain |
| | duc- | crystal | sizes that exceed 2.5 | crystal | sizes that exceed 2.5 | crystal | sizes that exceed 2.5 | crystal | sizes that exceed 2.5 |
| | tion | grain | times the average | grain | times the average | grain | times the average | grain | times the average |
| | sym- | size | crystal grain size | size | crystal grain size | size | crystal grain size | size | crystal grain size |
| Type | bol | (mm) | (%) | (μm) | (%) | (μm) | (%) | (μm) | (%) |
| Example 1 | A | 55 | 55 | 100 | 32 | 50 | 22 | 11 | 7.3 |
| Example 2 | B | 55 | 50 | 110 | 31 | 56 | 19 | 13 | 6.9 |
| Example 3 | C | 60 | 60 | 105 | 35 | 62 | 23 | 8 | 6.3 |
| Example 4 | D | 50 | 60 | 103 | 33 | 62 | 19 | 12 | 8.1 |
| Example 5 | E | 55 | 65 | 107 | 36 | 49 | 24 | 11 | 6.1 |
| Example 6 | F | 50 | 55 | 112 | 30 | 53 | 20 | 11 | 3.1 |
| Example 7 | G | 60 | 55 | 109 | 39 | 42 | 19 | 7 | 0 |
| Example 8 | H | 55 | 50 | 98 | 39 | 58 | 23 | 15 | 7.9 |
| Example 9 | I | 55 | 55 | 101 | 28 | 45 | 25 | 9 | 4.8 |
| Example 10 | J | 55 | 60 | 97 | 30 | 43 | 18 | 1 | 4.1 |

TABLE 3

| | Hot forging | | Warm forging | | Cold rolling | | | Stress relief | |
|---|---|---|---|---|---|---|---|---|---|
| | Forging | Water quenching | Forging | Water quenching | Total | Target | Water quenching | annealing | |
| Production | temperature | start temperature | temperature | start temperature | reduction | diameter | start temperature | Temperature | Time |
| symbol | (° C.) | (° C.) | (° C.) | (° C.) | ratio (%) | (mm) | (° C.) | (° C.) | (min) |
| a | 452 | 362 | 424 | 288 | 60 | 530 | 40 | 300 | 120 |
| b | 949 | 650 | 413 | 246 | 80 | 530 | 50 | 300 | 120 |
| c | 789 | 598 | 293 | 83 | 50 | 460 | 40 | 300 | 120 |
| d | 723 | 590 | 592 | 372 | 70 | 460 | 50 | 300 | 120 |
| e | 735 | 583 | 430 | 287 | 35 | 460 | 120 | 300 | 120 |
| f | 842 | 552 | 411 | 289 | 45 | 530 | 110 | 300 | 120 |
| g | 802 | 513 | 425 | 293 | 70 | 530 | 40 | 150 | 120 |
| h | 650 | 458 | 450 | 274 | 60 | 530 | 40 | 450 | 120 |
| i | 473 | 342 | 238 | 80 | 38 | 460 | 40 | 150 | 120 |
| j | 934 | 630 | 269 | 82 | 42 | 460 | 50 | 450 | 120 |

TABLE 4

| | | High-purity copper ingot with | | Hot-forged | | Warm-forged | | Stress-relief- | |
|---|---|---|---|---|---|---|---|---|---|
| | | unidirectionally solidified structure | | material | | material | | annealed material | |
| | | | Area ratio of crystal | | Area ratio of crystal | | Area ratio of crystal | | Area ratio of crystal |
| | Pro- | Average | grains having grain | Average | grains having grain | Average | grains having grain | Average | grains having grain |
| | duc- | crystal | sizes that exceed 2.5 | crystal | sizes that exceed 2.5 | crystal | sizes that exceed 2.5 | crystal | sizes that exceed 2.5 |
| | tion | grain | times the average | grain | times the average | grain | times the average | grain | times the average |
| | sym- | size | crystal grain size | size | crystal grain size | size | crystal grain size | size | crystal grain size |
| Type | bol | (mm) | (%) | (μm) | (%) | (μm) | (%) | (μm) | (%) |
| Comparative | a | 50 | 55 | 80 | 32 | 51 | 22 | 20 | 15 |
| Example 1 | | | | | | | | | |
| Comparative | b | 50 | 50 | 250 | 31 | 180 | 19 | 25 | 14 |
| Example 2 | | | | | | | | | |
| Comparative | c | 50 | 60 | 131 | 35 | 50 | 23 | 22 | 19 |
| Example 3 | | | | | | | | | |
| Comparative | d | 50 | 60 | 143 | 33 | 180 | 19 | 35 | 18 |
| Example 4 | | | | | | | | | |
| Comparative | e | 60 | 65 | 107 | 36 | 49 | 24 | 48 | 19 |
| Example 5 | | | | | | | | | |
| Comparative | f | 50 | 55 | 112 | 30 | 53 | 20 | 51 | 22 |
| Example 6 | | | | | | | | | |
| Comparative | g | 55 | 55 | 109 | 39 | 42 | 19 | Worked structure | |
| Example 7 | | | | | | | | remains; Immeasurable | |
| Comparative | h | 55 | 50 | 98 | 39 | 58 | 23 | 62 | 22 |
| Example 8 | | | | | | | | | |
| Comparative | i | 60 | 55 | 92 | 28 | 50 | 25 | Worked structure | |
| Example 9 | | | | | | | | remains; Immeasurable | |
| Comparative | j | 60 | 60 | 213 | 30 | 41 | 18 | 64 | 29 |
| Example 10 | | | | | | | | | |

Next, by using each of the worked high-purity copper materials of Examples 1 to 10 and Comparative Examples 1 to 10, three targets having a diameter of 152.4 mm and a thickness of 6 mm were manufactured from arbitrary places of the copper material through mechanical working (processing). Then, the targets were joined to a backing plate through indium soldering. Each of the targets was mounted in a sputtering apparatus, and the sputtering apparatus was evacuated to a final vacuum pressure of 1×10⁻⁵ Pa or less. Next, ultrapure Ar gas (purity: 5N) was used as sputtering gas, and pre-sputtering was carried out for 30 minutes under conditions of a sputter gas pressure: 0.3 Pa and a sputter output by a direct power supply: 0.5 kW. Next, sputtering was carried out continuously for 5 hours at 1.5 kW. During the sputtering, the number of abnormal discharges was counted using an arcing counter connected to the power supply, and an average number of abnormal discharges per hour was obtained.

The results are shown in Table 5.

TABLE 5

| | | Average number of |
|---|---|---|
| | | occurrences of abnormal |
| Type | | discharge (per hour) |
| Examples | 1 | 0.67 |
| | 2 | 0.87 |
| | 3 | 0.73 |
| | 4 | 0.93 |
| | 5 | 0.67 |
| | 6 | 0.60 |
| | 7 | 0.47 |
| | 8 | 0.93 |
| | 9 | 0.67 |
| | 10 | 0.53 |
| Comparative | 1 | 3.2 |
| Examples | 2 | 2.8 |
| | 3 | 2.9 |
| | 4 | 2.7 |
| | 5 | 6.8 |
| | 6 | 7.1 |
| | 7 | 8.2 |
| | 8 | 6.8 |
| | 9 | 8.3 |
| | 10 | 5.9 |

From the results shown in Table 5, it is found that, in the case where sputtering targets manufactured from the worked high-purity copper materials of the embodiment having uniform and fine crystal grains (Examples 1 to 10) are used, abnormal discharge is suppressed, and stable sputtering can be carried out even when the size of the targets is increased.

In contrast, in the case where sputtering targets manufactured from the worked high-purity copper materials of Comparative Examples (Comparative Examples 1 to 10) were used, the occurrence of abnormal discharge was observed, and sputtering became unstable. Therefore, it is considered that the occurrence of defects cannot be prevented in a sputtered film formed on a wafer.

As a use of the worked high-purity copper material having a uniform and fine crystalline structure of the embodiment, a target was exemplified in the description; however, the use of the worked high-purity copper material is not limited thereto. The worked high-purity copper material having a uniform and fine crystalline structure of the embodiment can be used as, for example, an electroplating anode. In this case, compared to an ordinary anode, dissolution is uniformly carried out. In addition, generation of black films can also be carried out uniformly.

### INDUSTRIAL APPLICABILITY

In the case where a sputtering target is manufactured using the worked high-purity copper material according to an aspect of the invention, and sputtering is carried out using the sputtering target, the occurrence of abnormal discharge can be prevented, and a conductive film having a uniform thickness can be formed. Therefore, the worked high-purity copper material and the production method thereof according to the aspect of the invention can be preferably applied to, for example, a step of producing a sputtering target for forming a conductive film on a silicon wafer.

1. A worked high-purity copper material having a uniform and fine crystalline structure, comprising:
Cu having a purity of 99.9999% by mass or more,
wherein an average crystal grain size is in a range of 20 μm or less, and, in a grain size distribution of crystal grains, an area ratio of crystal grains having grain sizes that exceed 2.5 times the average crystal grain size is in a range of less than 10% of an area of the entire crystal grains.

2. The worked high-purity copper material having a uniform and fine crystalline structure according to claim 1,
wherein the worked high-purity copper material is a sputtering target.

3. A method for producing the worked high-purity copper material having a uniform and fine crystalline structure according to claim 1, the method comprising:
subjecting an ingot composed of high-purity copper having a Cu purity of 99.9999% by mass or more to hot forging at an initial temperature of 550° C. or higher, and then water-cooing the ingot;
subsequently, subjecting the ingot to warm forging at an initial temperature of 350° C. or higher, and then water-cooing the ingot;
subsequently, subjecting the ingot to cold cross-rolling at a total reduction ratio of 50% or more; and
subsequently, subjecting the ingot to stress relief annealing at a temperature of 200° C. or higher.

4. The method for producing the worked high-purity copper material having a uniform and fine crystalline structure according to claim 3,
wherein, as the ingot composed of the high-purity copper having a purity of 99.9999% by mass or more, a high-purity copper ingot is used that is produced through unidirectional solidification and has no casting defects composed of shrinkage cavities or voids.

5. The method for producing the worked high-purity copper material having a uniform and fine crystalline structure according to claim 3,
wherein, in the hot forging, hot forging of stretching or compressing is carried out at least one or more times at an initial temperature of 550° C. to 900° C.

6. The method for producing the worked high-purity copper material having a uniform and fine crystalline structure according to claim 5,
wherein, in the hot forging of stretching or compressing, the ingot is compressed in a solidification direction, and then the ingot is stretched while the ingot is forged in multi-directions of at least two or more directions which are perpendicular to the solidification direction of the ingot.

7. The method for producing the worked high-purity copper material having a uniform and fine crystalline structure according to claim 3,
wherein, in the warm forging, warm forging of stretching or compressing is carried out at least one or more times at an initial temperature of 350° C. to 500° C.

8. The method for producing the worked high-purity copper material having a uniform and fine crystalline structure according to claim 7,
wherein, in the warm forging of stretching or compressing, the ingot is compressed in a solidification direction, and then the ingot is stretched while the ingot is forged in multi-directions of at least two or more directions which are perpendicular to the solidification direction of the ingot.

9. The method for producing the worked high-purity copper material having a uniform and fine crystalline structure according to claim 3,
wherein the stress relief annealing is carried out in a temperature range of 200° C. to 400° C.
